(19) United States
(12) Patent Application Publication
(10) Pub. No.: US 2006/0045969 A1
(43) Pub. Date: Mar. 2, 2006

(54) Apparatus for manufacturing semiconductor device and method for manufacturing semiconductor device

(75) Inventors: Ichiro Yamamoto, Kanagawa (JP); Koji Watanabe, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, Kanagawa (JP)

(21) Appl. No.: 11/208,787

(22) Filed: Aug. 23, 2005

(30) Foreign Application Priority Data
Aug. 25, 2004 (JP) 2004-245306

(51) Int. Cl. C23C 16/00

(52) U.S. Cl. 427/248.1

(57) ABSTRACT

Variation in the thickness of the deposited films depending on number of the processed product wafers in the deposition process employing a batch type CVD apparatus is inhibited to provide a manufacture of the film having a predetermined thickness with an improved reproducibility. The deposition apparatus 100 comprises a deposition reactor 101 that is capable of containing product wafers 107 and dummy wafers 109, boat 105, on which product wafer 107 or the dummy wafer 109 is mounted, and a heater 111 provided outside of the deposition reactor 101 along a reactor wall 103. Further, the deposition apparatus 100 comprises a gas supplying system including a high-k source material supplying line 113 and SiO₂ source material supplying line 115, and a controller 121 that provides a control to the supply of a gas from the gas supplying system to the deposition reactor 101.

This application is based on Japanese patent application NO. 2004-245306, the content of which is incorporated hereinto by reference.

### BACKGROUND OF THE INVENTION

1. Field of the Invention

The present invention relates to an apparatus for manufacturing a semiconductor device and a method for manufacturing a semiconductor device.

2. Description of the Related Art

In recent years, the utilization of a film having high dielectric constant called high-k as a component material for semiconductor devices is actively investigated. Typical high-k materials include oxides of elements such as Zr, Hf and the like. Japanese Patent Laid-Open No. 2004-31,760 describes that high dielectric constant film such as HfSiO is employed for a gate insulating film. The use of such materials for a gate insulating film of a MOSFET reduces an equivalent oxide thickness, even though the physical thickness of the gate insulating film is increased to a certain level, thereby providing physically and structurally stable gate insulating films.

A batch type chemical vapor deposition (CVD) apparatus is generally used for depositing such high dielectric constant film.

### SUMMARY OF THE INVENTION

When the batch type CVD apparatus is employed, a dummy wafer (non product wafer) is employed simultaneously with a product wafer. The dummy wafer is utilized for the purpose of maintaining a constant consumption of gas between batches, maintaining a constant radiation of heat in batch type reactor between batches, or maintaining an identical composition of the film between batches.

When thin films are deposited in the batch type CVD apparatus, stable achievement of providing a constant target film thickness deposited on the product wafers regardless of number of the product wafers loaded in the reactor is required for the mass production apparatus. However, the present inventors have examined the conventional batch type CVD apparatus, and found that a phenomena was occurred that the thicknesses of the deposited films were somewhat varied depending upon number of the processed product wafers and number of processed dummy wafers, even if all depositions were conducted under the identical process condition.

The present inventors have eagerly investigated for finding a possible cause of varying the thickness of the deposited films on the product wafer depending upon the ratio of processed product wafers/dummy wafers when the ratio of numbers of the processed product wafers/dummy wafers in the whole wafers simultaneously treated is changed. As a result, it was suspected that the variation in the film thickness was caused because the surface states of the interior of the chamber and of the dummy wafer are different from the surface state of the product wafer.

More specifically, a deposition process employing a deposition apparatus having a configuration shown in FIG. 6A and FIG. 6B was examined. FIG. 6A and FIG. 6B are cross-sectional views, schematically showing a configuration of a conventional deposition apparatus. A deposition apparatus 200 shown in FIG. 6A and FIG. 6B is a batch type CVD deposition apparatus that is capable of simultaneously conducting a deposition process for a plurality of semiconductor substrates, specifically, silicon wafers in this case.

The deposition apparatus 200 comprises a deposition reactor 201, boat 205 contained in the deposition reactor 201 and a heater 211 provided outside of the deposition reactor 201 along the chamber wall 203. In addition, the deposition apparatus 200 has high-k source material-feeding tubes 213. High-k source material feeding tubes 213 are a plurality of tubes for introducing a source gas for depositing certain films on the product wafers 207 in the deposition reactor 201.

The boat 205 is retrievably housed within the deposition reactor 201. Certain numbers of the product wafers 207 and dummy wafers (non product wafers) 209 are mounted on the boat 205. Total number of the product wafers 207 and the dummy wafers 209 contained within the deposition reactor 201 in one batch deposition process is set to a predetermined number depending upon the scale of the deposition reactor 201, and the predetermined pieces of the whole wafers are contained in the deposition reactor 201 in each batch.

The deposition sequence conducted by utilizing the deposition apparatus 200 shown in FIG. 6A and FIG. 6B is briefly described as follows, though will be described in a comparative example discussed later in detail. First, after the deposition of the previous batch is completed, the dummy wafers 209 and the product wafers 207 are unloaded. Then, a certain number of the product wafers 207 having SiO₂ film 225 on the surface thereof and a certain number of the dummy wafers 209 are loaded in the deposition reactor 201. Then, HfSiOₓ (hereinafter, x indicates a positive integer number) is deposited (to a thickness of on the order of 1 to 2 nm), and thereafter the deposited film is nitrided.

The present inventors conducted an experimental approach, in which several batch processing were carried out for different number of product wafers 207 provided that total number of the product wafers 207 and the dummy wafers 209 was constant. Then, the processed dummy wafers 209 and the product wafers 207 were unloaded from the deposition reactor 201, and the thicknesses of HfSiON films formed on the surfaces of the wafers were measured. As can be seen from FIG. 7 that will be referred in the description of the comparative example discussed later, it was found that larger number of the product wafers 207 in one batch provides larger thickness of the deposited HfSiOₓ film.

The reason for the phenomenon is considered as follows. When the HfSiON film 223, which is a high dielectric constant gate insulating film, is deposited by the process stated above, for example, HfSiON film 223 is first obtained by depositing HfSiOₓ film via a CVD and then thermally processing the HfSiOₓ film with NH₃ to form HfSiON. The deposition rate for the HfSiOₓ film in the first step in these process steps depends on the material of the surface to be deposited, and it is expected that a hierarchy of the deposition rates by the surface materials are as (on HfSiON)>(on SiO₂)>(on HfSiOₓ). Thus, larger occupancy of the dummy wafer 209 in the total number of product/dummy wafers loaded in the deposition reactor 201 would provide larger consumption of the source gas used in the circumference of the dummy wafer 209, thereby decreasing the thickness of the film deposited on the surface of the product wafer 207.

As such, in the conventional method, the difference in the deposition rates for the HfSiOₓ film between the film deposited on the surface of the dummy wafer and the film deposited on the surface of the product wafer results in varying the thickness of the HfSiOₓ film deposited on the product wafer corresponding to number of the loaded product wafers in one batch. Consequently, in accordance with the result of the above described studies, the present inventors have investigated in order to provide a method that can achieve the deposition of the thin film having a certain thickness on the product wafer with an improved reproducibility, independently with respect to number of the product wafers housed within the deposition reactor, and thus leads to the present invention.

According to one aspect of the present invention, there is provided an apparatus for manufacturing a semiconductor device via a batch process, adopted to simultaneously deposit films on a plurality of semiconductor wafers, comprising: a deposition reactor being capable of containing a product wafer and a dummy wafer (non product wafer) in the deposition reactor; a first gas supplying system that supplies a first gas into the deposition reactor; and a second gas supplying system that supplies a second gas into the deposition reactor, wherein the first gas is a source gas for a predetermined film deposited on a surface to be deposited of the product wafer, and wherein the second gas is a source gas of a pre-coating film, which is to be deposited on the dummy wafer and different in composition from the predetermined film.

The apparatus for manufacturing the semiconductor device according to the aspect of the present invention comprises the first gas supplying system and the second gas supplying system. The second gas supplying system supplies a source material for the pre-coating film deposited on the dummy wafer. Thus, the pre-coating film can be provided on the dummy wafer before depositing a certain film on the product wafer. Thus, type of the material for the surface of the dummy wafer can be established depending on the material for the surface of the product wafer. Therefore, even if the occupancy of the product wafers in the sum of the product wafers and the dummy wafers in one batch is changed, a change in the thickness of the predetermined film provided on the product wafer can be inhibited. Therefore, stable reproducibility in the film thickness among the deposited films can be obtained regardless of the number of the product wafers and the dummy wafers. Thus, the fluctuation in the film thickness by batch can be inhibited in the batch type apparatus for manufacturing the semiconductor.

According to another aspect of the present invention, there is provided a method for manufacturing a semiconductor device comprising a deposition process for collectively forming predetermined films on surfaces of a plurality of semiconductor wafers, the deposition process includes: preparing at least one piece of dummy wafer (non product wafer) having a pre-coating film on the dummy wafer, which is different in composition from the predetermined film; and providing the predetermined films simultaneously on the surface of the dummy wafer prepared in the preparing the dummy wafer and on a surface of a product wafer.

The method for manufacturing the semiconductor device according to the aspect of the present invention comprises preparing the dummy wafer having the pre-coating film thereon, which is different in composition from the predetermined film deposited on the product wafer. The predetermined film is simultaneously deposited on the dummy wafers having the pre-coating film provided thereon and on the product wafers. Thus, when certain films are provided, the dummy wafers having pre-coating films that is suitable to the material of the product wafers can be employed, according to material of the product wafer. Therefore, even if the occupancy of the product wafers in the sum of the product wafers and the dummy wafers in one batch is changed, a change in the thickness of the predetermined film provided on the product wafer can be inhibited, thereby achieving depositions with higher reproducibility.

The apparatus for manufacturing the semiconductor device according to the above-described aspect of the present invention may further have a configuration, in which the predetermined film contains O and one or more metal(s) selected from the group consisting of Hf, Al and Zr. In addition, the method for manufacturing the semiconductor devices according to the above-described aspect of the present invention may further have a configuration, in which the simultaneously providing the predetermined films includes providing a predetermined film containing 0 and one or more metal(s) selected from the group consisting of Hf, Al and Zr on the surfaces of the dummy wafer and the product wafer. Having such configurations, variation in the thickness of the deposited films in the deposition of the oxide films of above-described metal can be inhibited.

In the above-described aspects of the present invention, the predetermined film may be a film further containing elemental Si and/or elemental N.

The apparatus for manufacturing the semiconductor device according to the above-described aspect of the present invention may further have a configuration, in which the surface to be deposited of the product wafer is a surface of a film of a metal, a metal oxide or a metal nitride, and the second gas supplying system is adapted to pre-coating a film in the interior of the deposition reactor, the film being composed of a material that is the same as the material of the film deposited on the surface to be deposited of the product wafer.

In addition, the method for manufacturing the semiconductor devices according to the above-described aspect of the present invention may further have a configuration, in which the preparing the dummy wafer includes providing a film on the surface of the dummy wafer, the film being composed of a material that is the same as the material of the surface to be deposited of the product wafer, and wherein the simultaneously providing the predetermined films includes providing the film of a material that is different from the material of the surface to be deposited of the product wafer.

Having such configurations, the material for the surface to be deposited of the dummy wafer can be selected to be similar to the material of the product wafer. Therefore, variation in the thickness of the deposited films caused by batch can be surely reduced when predetermined film is deposited on the product wafers.

In the above-described aspects of the present invention, the surface to be deposited of the product wafer may be a surface of a film composed of any of a metal, a metal oxide and a metal nitride.

The apparatus for manufacturing the semiconductor device according to the above-described aspect of the present invention may further have a configuration, in which the surface to be deposited of the product wafer is a surface of a SiO₂ film, and the pre-coating film is a SiO₂ film. In addition, the method for manufacturing the semiconductor devices according to the above-described aspect of the present invention may further have a configuration, in which the surface to be deposited of the product wafer is a surface of a SiO₂ film, and wherein the preparing the dummy wafer includes pre-coating a SiO₂ film on the surface of the dummy wafer. Having such configurations, variation in the thickness of the deposited films can be inhibited when the predetermined film is deposited on the SiO₂ films on the product wafers.

The apparatus for manufacturing the semiconductor device according to the above-described aspect of the present invention may further have a configuration, in which the surface to be deposited of the product wafer is a surface of a TiN film, and the pre-coating film is a TiN film. In addition, the method for manufacturing the semiconductor devices according to the above-described aspect of the present invention may further have a configuration, in which the surface to be deposited of the product wafer is a surface of a TiN film, and wherein the preparing the dummy wafer includes pre-coating a TiN film on the surface of the dummy wafer. Having such configurations, variation in the thickness of the deposited films can be inhibited when the predetermined film is deposited on the TiN films on the product wafers.

The apparatus for manufacturing the semiconductor device according to the above-described aspect of the present invention may further have a configuration, in which the apparatus further comprises a controller that controls the first gas supplying system and the second gas supplying system, wherein the controller is adapted to supply the second gas to the interior of the deposition reactor from the second gas supplying system while the dummy wafer is contained within the deposition reactor, and to supply the first gas to the interior of the deposition reactor from the first gas supplying system while the dummy wafer having the pre-coating film on the surface thereof and the product wafer are contained within the deposition reactor. Having such configuration, the pre-coating films and the target films can be deposited at a preferable timing. Thus, variation in the thickness of the deposited films on the product wafers can be more surely reduced.

The method for manufacturing the semiconductor devices according to the above-described aspect of the present invention may further have a configuration, in which the preparing the dummy wafer includes containing the dummy wafer within a batch type deposition reactor that is adopted to simultaneously deposit films on a plurality of semiconductor wafers, and providing the pre-coating film on the surface of the dummy wafer and on the wall of the deposition reactor, wherein the simultaneously providing the predetermined films is conducted within the deposition reactor having the pre-coating film provided in the deposition reactor. According to such configuration, pre-coating film can be deposited on the wall of the deposition reactor in addition to the surfaces of the dummy wafers, and therefore the reproducibility in the film thickness among the depositions onto the product wafers can be still further improved.

It is to be understood that the invention is capable of use in various other combinations, modifications, and environments, and any other exchanging of the expression between the method and device or the like according to the present invention may be effective as an alternative of an embodiment according to the present invention.

For example, in the present invention, an alternative configuration may comprise a heating section that can heat the aforementioned deposition reactor.

In addition, in the present invention, the aforementioned controller may be configured to provide a suitable adjustment of the number of the dummy wafers contained in the deposition reactor according to the number of the product wafers contained in the deposition reactor. Having such configuration, the deposition operation can more easily be carried out.

According to the present invention, there is provided a technology for providing an inhibition of a variation in the thickness among the deposited films depending on number of the processed product wafers in the deposition process employing a batch type CVD apparatus to provide a manufacture of the film having a predetermined thickness with an improved reproducibility.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view, schematically showing a configuration of a deposition apparatus according to an embodiment;

FIGS. 2A and 2B are cross-sectional views, illustrating a deposition method utilizing the deposition apparatus according to the embodiment;

FIGS. 3A and 3B are cross-sectional views, illustrating a deposition method utilizing the deposition apparatus according to the embodiment;

FIG. 4 is a flow chart of a deposition procedure according to the embodiment;

FIG. 5 is a flow chart of a deposition procedure according to the embodiment;

FIGS. 6A and 6B are cross-sectional views, schematically showing a configuration of a conventional deposition apparatus according to an embodiment; and

FIG. 7 is a graph, showing a relationship between number of the product wafers and thickness of the HfSiOₓ film in a deposition method of a comparative example.

### DETAILED DESCRIPTION OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purpose.

Embodiments according to the present invention will be described as follows in further detail, in reference to the annexed figures. In all figures, identical numeral is assigned to an element commonly appeared in the figures, and the detailed description thereof will not be presented. In addition, the descriptions in the following embodiments will be made in reference to cases that the configurations of the present invention are applied to batch type hot wall CVD apparatus.

### First Embodiment

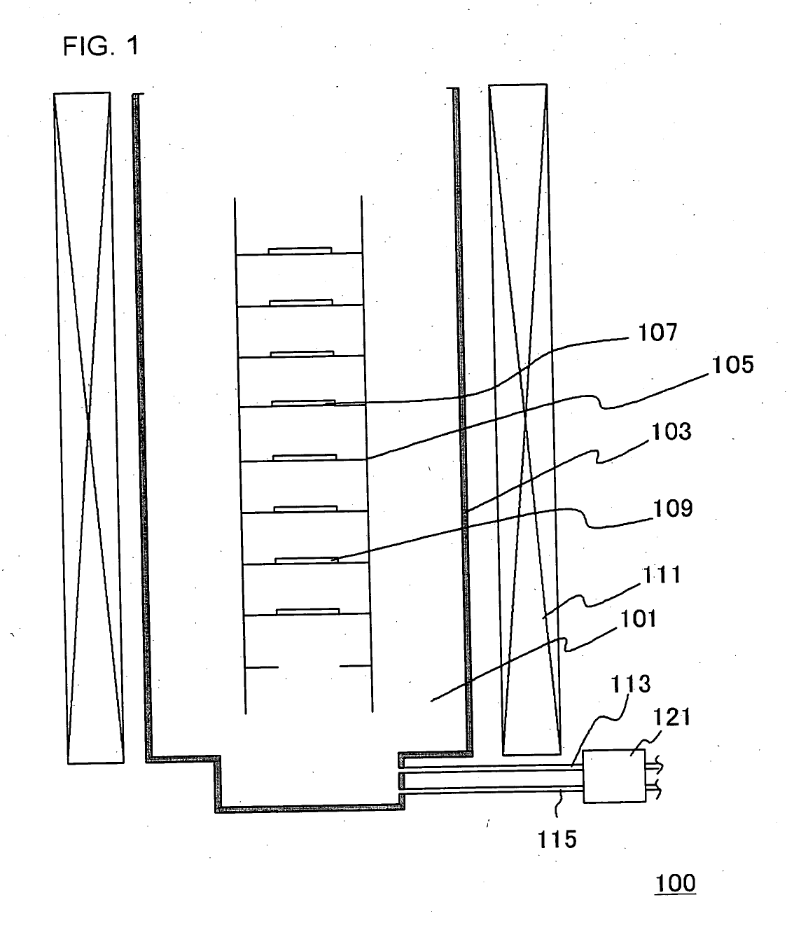

FIG. 1 is a cross-sectional view, schematically illustrating a configuration of a deposition apparatus according to the present embodiment. A deposition apparatus 100 shown in FIG. 1 is a batch type CVD deposition apparatus that is capable of simultaneously conducting a deposition process for a plurality of semiconductor substrates, specifically, silicon wafers in this case.

The deposition apparatus 100 comprises a deposition reactor 101 that is capable of containing product wafers 107 and dummy wafers (non product wafers) 109, boat 105, on which product wafer 107 or the dummy wafer 109 is mounted, and a heater 111 provided outside of the deposition reactor 101 along a reactor wall 103. Further, the deposition apparatus 100 comprises a gas supplying system including a high-k source material supplying line 113 and SiO₂ source material supplying line 115, and a controller 121 that provides a control to the supply of a gas from the gas supplying system to the deposition reactor 101.

The boat 105 is retrievably housed in the interior of the deposition reactor 101. In the boat 105, certain number of the product wafers 107 and the dummy wafers 109 are mounted. Total number of the product wafers 107 and the dummy wafers 109 contained in the deposition reactor 101 in one batch deposition process is selected as a certain number according to the scale of the deposition reactor 101, and each batch processing is carried out for the selected total number of wafers.

The high-k source material supplying line 113 is a bundle of a plurality of lines for introducing into the deposition reactor 101 a source gas for depositing a certain film on the product wafer 107. The SiO₂ source material supplying line 115 is a bundle of a plurality of lines for introducing into the deposition reactor 101 a source gas for depositing a pre-coating film provided on the dummy wafer 109 prior to the deposition process over the product wafer 107. Opening and shutting of each tube composing the high-k source material supplying line 113 and the SiO₂ source material supplying line 115 are controlled by the controller 121.

An exemplary implementation of the case in which the pre-coating film is a SiO₂ film same as a base SiO₂ film 125 and a film deposited on the product wafer 107 is an HfSiON film will be described.

In the conventional method described above, the deposition of HfSiON film has been conducted under the situation where the types of the films formed on the surfaces of product wafer 107 and the dummy wafer 109 are different. In this case, variation in the thickness of the deposited HfSiON films formed on the product wafer 107 has been occurred, depended on the number of the processed product wafers 107. In the present embodiment, the deposition process according to the following procedures is adopted in order to inhibit such variation in the thickness of the deposited film.

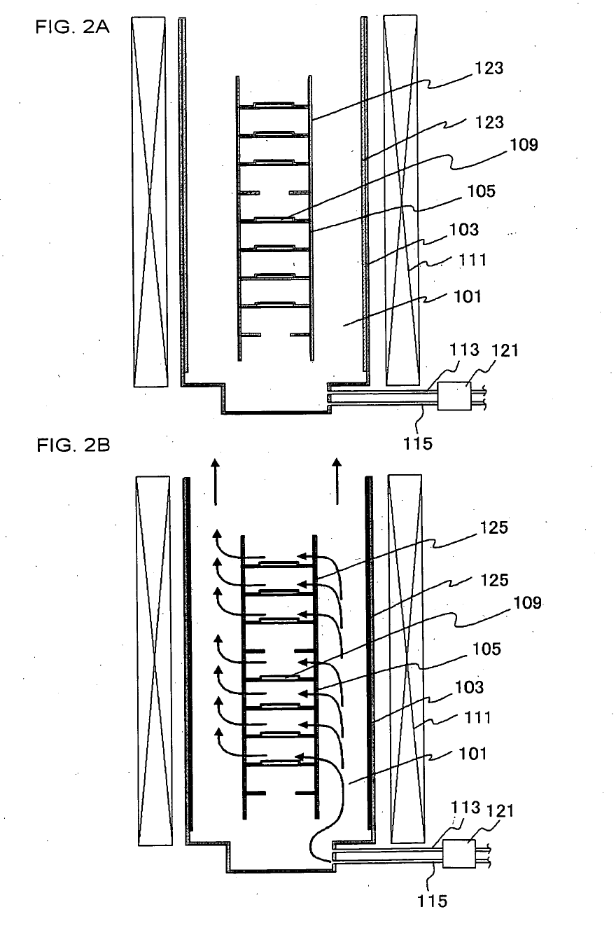

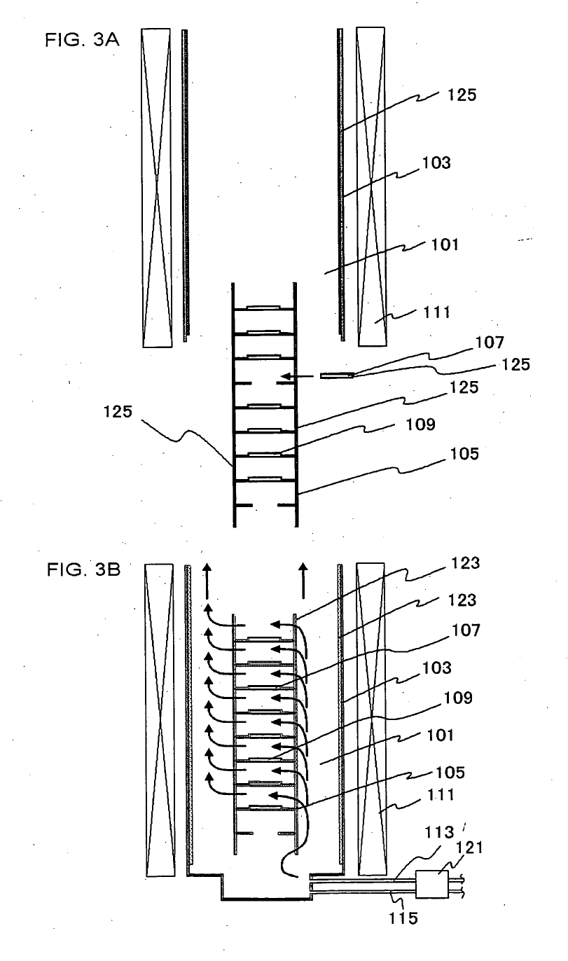

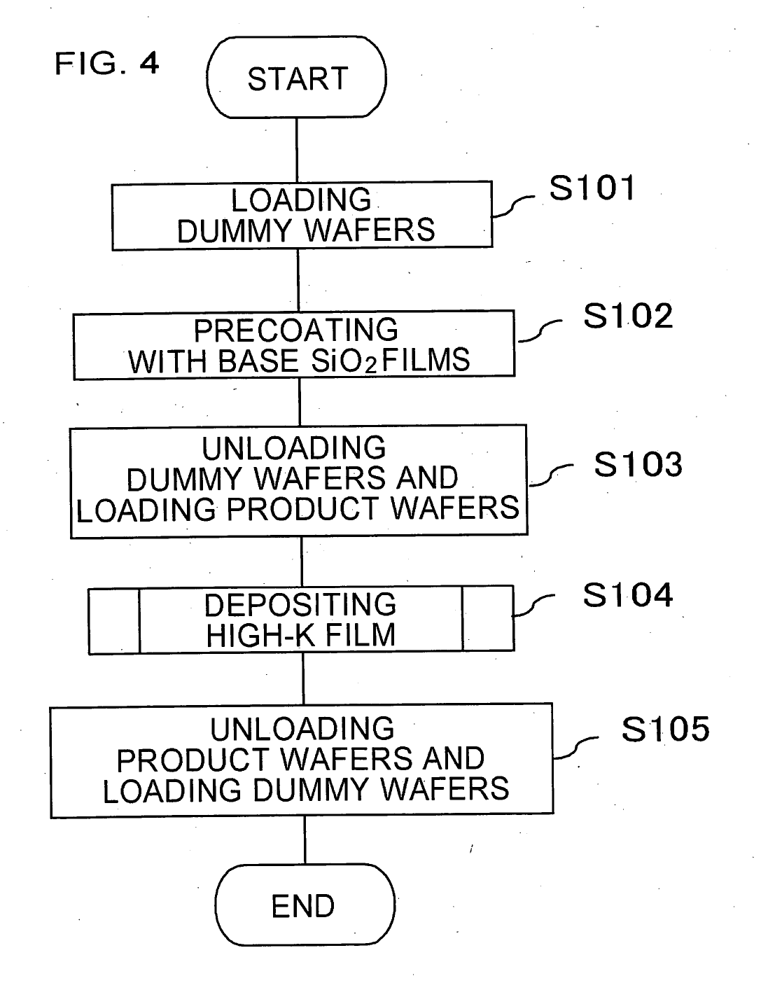

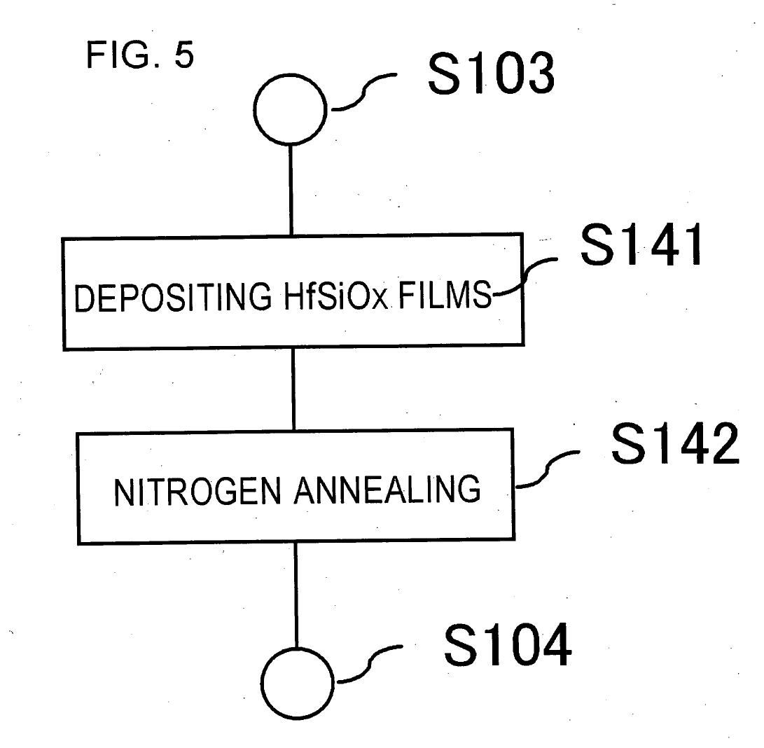

FIG. 2A, FIG. 2B, FIG. 3A and FIG. 3B are cross-sectional views that are useful for describing the deposition method utilizing the deposition apparatus 100 shown in FIG. 1. FIG. 4 and FIG. 5 are flow charts for the deposition procedure utilizing the deposition apparatus 100 shown in FIG. 1. The deposition method utilizing the deposition apparatus 100 will be described as follows, in reference to these figures.

FIG. 2A is a diagram, showing the deposition apparatus 100 in a condition just after the batch processing is completed. This indicates a status of just after a serial deposition process is completed and before the beginning of next serial deposition process. On the inside of the reactor wall 103, on the surface of the boat 105 and on the surfaces of the dummy wafers 109 are provided with HfSiON films 123 that have been deposited in the previous batch.

In the subsequent batch process, as shown in FIG. 2B, the boat 105 is loaded in the deposition reactor 101 while the dummy wafers 109 are mounted thereon (S101 of FIG. 4). The number of the dummy wafers 109 in this occasion is presented by subtracting the number of product wafers 107 that are expected to be loaded in the deposition reactor 101 in the subsequent process from the total number of the wafers.

Then, a SiO₂ deposition source gas is introduced from the SiO₂ source material supplying line 115 to provide a pre-coating film of SiO₂ on the surfaces of the reactor wall 103, the boat 105 and the dummy wafers 109 (S102 of FIG. 4). The SiO₂ deposition source gas in step S102 may be, for example, a gaseous mixture of tetraethoxysilane (TEOS) and O₂. The film thickness of the base SiO₂ film 125 may be, for example, on the order of 1 to 10 nm. These conditions would provide preferable effects as the pre-coating film.

Next, as shown in FIG. 3A, the dummy wafers 109 and the boat 105 are unloaded. Then, a certain number of the product wafers 107 are mounted onto the unloaded boat 105 (S103 of FIG. 4). The surfaces to be deposited of the product wafers 107 are surfaces of the SiO₂ films. Thereafter, the boat 105 having product wafers 107 and the dummy wafers 109 mounted thereon is loaded back into the deposition reactor 101 again. In this status, all exposed surfaces within the inside of the deposition reactor 101 are SiO₂.

Then, as shown in FIG. 3B, HfSiON film 123 is formed as a high dielectric constant film (high-k film) on the surface of the product wafer 107 that has a surface of SiO₂ films for the surface to be deposited (S104 of FIG. 4). Step S104 consists of the deposition of HfSiOₓ film (S141 of FIG. 5) and the nitrogen annealing (S142 of FIG. 5).

Gaseous mixture of tertiary butoxy hafnium (HTB, Hf (Ot-Bu)₄) and SiH₄ or Si₂H₆ is employed as the deposition source gas for HfSiOₓ in step S141 (FIG. 5), In step S141, HfSiOₓ films are deposited on the surfaces of the product wafers 107, the dummy wafers 109 and the boat 105 and on the inside of reactor wall 103. It should be noted that these surfaces to be deposited are all SiO₂ films, and thus HfSiOₓ film are deposited at substantially identical deposition rate on the product wafer 107 and on the dummy wafer 109. The film thickness of the deposited HfSiOₓ film is set to be, for example, on the order of 1 to 2 nm.

Further, the nitriding process in step S142 (FIG. 5) may be conducted by employing, for example, NH₃.

After the deposition of the HfSiON film 123, the product wafers 107 and the dummy wafers 109 are unloaded together with the boat 105 (S105 of FIG. 4). HfSiON films 123 having a certain film thickness can be simultaneously deposited on a certain number the product wafers 107 by the above-mentioned procedure.

In the above-mentioned deposition procedure, the controller 121 provides the timings for supplying the high-k source gas and the SiO₂ source gas are controlled by controlling the opening and shutting status of the High-k source material supplying lines 113 and the SiO₂ source material supplying lines 115. More specifically, the controller 121 provides an opening status for each cock (not shown) provided to each of a plurality of SiO₂ source material supplying lines 115 in step S102. Then, in step S103, a closing status is presented to each cock provided to each of a plurality of SiO₂ source material supplying lines 115. Then, in step S104, an opening status is presented to each cock (not shown) provided to each of a plurality of high-k source material supplying lines 113. Here, in step S101 and step S105, a closing status is presented to each cock provided to each of a plurality of SiO₂ source material supplying lines 115 and high-k source material supplying lines 113.

Next, advantageous effects obtainable by employing the deposition apparatus 100 shown in FIG. 1 will be described.

The deposition apparatus 100 shown in FIG. 1 has the SiO₂ source material supplying lines 115 separately from the high-k source material supplying lines 113. The pre-coating process for the dummy wafers 109 is conducted in every deposition process for the product wafers. The status of the surfaces in the interior of the deposition reactor 101 shortly before commencing the deposition process in step S104 of FIG. 4 can be prepared as a uniformly oxidized status by conducting a pre-coating with the pre-coating films. Thus, the high dielectric constant film, namely, HfSiOₓ film in this case, can be formed to a predetermined thickness with an improved reproducibility, regardless of the number of the product wafers 107.

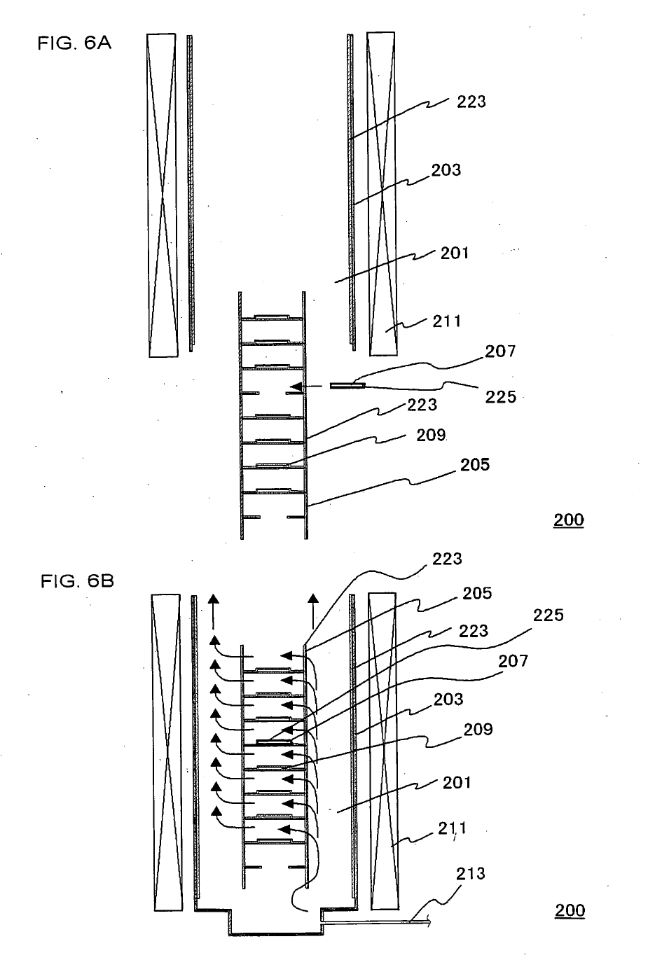

Here, unlikely with the deposition apparatus 100 shown in FIG. 1, the deposition apparatus 200 described above in reference to FIG. 6A and FIG. 6B has no SiO₂ source material supplying line 115. Further, in the deposition process for the conventional high dielectric constant film, the deliberate formation of the base SiO₂ film 125 of step S102 shown in FIG. 4 is not conducted. The hierarchy of the deposition rates of HfSiOₓ by the surface materials are as (on HfSiON)>(on SiO₂)>(on HfSiO), and the deposition rate depends upon the state of the surface. Thus, in conventional method that involves depositing a film while the wafers having different types of the surfaces to be deposited are simultaneously disposed within the deposition reactor 201, the amount of the consumed high-k source material depends upon the material for the surface to be deposited.

Thus, since larger amount of the source material is consumed on the dummy wafers 209 in the case of depositing films on larger number of dummy wafers 209, that is, larger surface area of HfSiON provided that a constant quantity of the source material is supplied into the batch type reactor, the whole consumption of the source material is increased, such that the amount of the source material supplied to the product wafer 207 is decreased, thereby reducing the film thickness of the deposited HfSiOₓ.

For example, when one piece of product wafer 207 containing the surface material of SiO₂ and 24 pieces of dummy wafers 209 are loaded therein, the periphery of the product wafer 207 is provided with the reactor wall 203 and the dummy wafers 209 that are coated with HfSiON. In this case, the deposition rate for HfSiO film is higher on the reactor wall 203 and the dummy wafers 209, and therefore larger amount of the source material is consumed. Thus, supply of the source material to the product wafers 207, which contain the surface material of SiO₂ that promotes lower deposition rate than that on HfSiON, tends to be a short supply, thereby reducing the thickness of HfSiO film on the product wafers 207.

Further, when the occupancy of the dummy wafers 209 in the sum of the wafers in one batch is decreased, or in other words, when the surface area of the HfSiON films is reduced, the consumption quantity of the source material on the dummy wafer 209 is decreased, such that the whole consumption of the source material in the deposition reactor 201 is decreased, and, in turn, sufficient amount of the source material is also supplied to the surface of the product wafers 207 having the surface of SiO₂, thereby providing increased thickness of the deposited HfSiON films. According such mechanism, the change in the occupancy of the dummy wafers 209 having HfSiON deposited thereon in the sum of the wafers in one batch would provide a change in the thickness of HfSiOₓ deposited on the product wafers.

For example, when 10 pieces of product wafers 207 containing the surface material of SiO₂ and 15 pieces of dummy wafer 209 are loaded therein, the amount of the source material supplied to the product wafer 207 is larger than the case where one piece of product wafer 207 and 24 pieces of dummy wafers 209 are loaded therein, since the surface area of HfSiON is smaller. As a result, larger thickness of the HfSiO film on the product wafer 207 is presented as compared with the case where one piece of product wafer 207 and 24 pieces of dummy wafers 209 are loaded therein.

On the contrary, in the process utilizing the deposition apparatus 100 according to the present embodiment (FIG. 1), the entire exposed surfaces in the interior of the deposition reactor 101 are pre-coated with SiO₂, prior to the deposition onto the product wafers 107 (S102 of FIG. 4). Having such processing, the status of depositing the identical films on the product wafers 107 and the dummy wafers 109 can be achieved, so that equivalent surface status can be presented to both wafers for depositing HfSiOₓ. Therefore, the change in the thickness of the deposited HfSiOₓ film depending on the number of the dummy wafers 109 can be inhibited. Further, since the interior of the deposition reactor 101 is coated with the base SiO₂ film 125, on which HfSiOₓ is not easily deposited, the consumption of Hf-containing source material is reduced. Thus, the high-k source gas can be efficiently consumed. This advantageous effect can be particularly exhibited in the case of depositing on the surface of the product wafer 107 a material that is resistant to being oxidized to form SiO₂.

While the above description is focused on the procedure for forming the HfSiON film by conducting the nitriding process after the deposition of the HfSiOₓ film, an operation of containing N into the film may also be added to the deposition process of step S141.

Further, in the above-mentioned deposition procedure, the surface of the product wafer 107 can be provided with HfSiOₓ film when the nitriding process of step S142 (FIG. 5) is not conducted. In this case, after the deposition is the previous batch is completed, HfSiOₓ films are deposited on the surfaces of the dummy wafers 109, on the inside of reactor wall 103 and on the surface of the boat 105. In this case, the pre-coating with the base SiO₂ film 125 of step S102 can provide an improved reproducibility in the film thickness among the HfSiOₓ films deposited in the subsequent batch processes.

Further, a combination of SiH₄ and N₂O may be employed as a source gas in the case of depositing the base SiO₂ film 125 in step S102 (FIG. 4). In addition, a combination of SiH₂Cl₂ and N₂O can also be employed as a source gas. When such source materials are employed, the SiO₂ source material supplying lines 115 may be separately provided in addition to the high-k source material supplying lines 113 and the timing for supplying the gases from these gas supplying lines to the deposition reactor 101 may be controlled by the controller 121, so that the pre-coating process in step S102 (FIG. 4) can be conducted.

In addition, in the above configurations, the film deposited on the surface of the product wafer 107 may be other high dielectric constant film. Further, it is not limited to high dielectric constant film, and other insulating films may also be employed. Further, deposited on the surface of the product wafer 107 may be of a material that is resistant to being oxidized to form SiO₂.

### Second Embodiment

In second embodiment, a film other than HfSiON film is deposited on the surface to be deposited of the product wafer 107. The type of the deposited film provided on the product wafer 107 may be, for example other high-k material. The available high-k material may be, for example, a material having a specific dielectric constant of equal to or higher than 10. For example, the film formed on the surface of the product wafer 107 may be composed of a material containing one or more metallic element(s) selected from the group consisting of Hf and Zr. Specifically, an oxide film, a silicate film or the like, containing one or more metallic element(s) selected from the group consisting of Hf, Al and Zr may be employed. More specifically, HfO₂, Al₂O₃, ZrO₂, ZrSiOₓ (hereinafter, x represents a positive integer number) or ZrSiON may be employed.

When the surface to be deposited of the product wafer 107 is provided with the HfO₂ film, the deposition source material supplied into the deposition reactor 101 through the high-k source material supplying line 113 may be, for example, a combination of HTB and any one of O₂, O₃ and H₂O.

When the surface to be deposited of the product wafer 107 is provided with the Al₂O₃ film, the deposition source material supplied into the deposition reactor 101 through the high-k source material supplying line 113 may be, for example, a combination of trimethylaluminum (TMA, Al(CH₃)₃) and O₃. Alternatively, a combination of TMA and H₂O may be employed.

When the surface to be deposited of the product wafer 107 is provided with the ZrO₂ film, the deposition source material supplied into the deposition reactor 101 through the high-k source material supplying line 113 may be, for example, a combination of tertiary butoxy zirconium (ZTB, Zr(O-tBu)₄) and any one of O₂, O₃ and H₂O.

When the surface to be deposited of product wafer 107 is provided with ZrSiOₓ film, the deposition source material supplied into the deposition reactor 101 through the high-k source material supplying line 113 may be, for example, a combination of ZTB and any one of SiH₄ or Si₂H₆.

When such source gases are employed, the pre-coating with the base SiO₂ film 125 of step S102 described above (FIG. 4) can provide an inhibition to the variation in the film thickness of the high dielectric constant film in the deposition of high-k film of step S104, even if the occupancy of the product wafers 107 in the sum of the wafers contained in the deposition reactor 101 in one batch is changed, thereby providing an improved reproducibility in the film thickness among the deposited films.

### Third Embodiment

While the above embodiments illustrate cases that the surface to be deposited of the product wafers 107 is a surface of SiO₂ film, and the surface of the boat 105, the interior wall of the deposition reactor 101 and the dummy wafers 109 are pre-coated with the base SiO₂ films 125, the configuration of the deposition apparatus 100 may also be applicable to the case that the surface to be deposited of the product wafer 107 is a surface of other type of film.

The material of the pre-coating film may be a material, which is different from the material of the surface to be deposited of the product wafer 107. In this occasion, the film provided on the surface of the product wafer 107 may be a film of a material other than the material of the surface to be deposited.

For example, when the surface to be deposited of the product wafer 107 is a surface of TiN film, TiN source material supplying lines may be provided to be connected to the deposition reactor 101, in place of the SiO₂ source material supplying lines 115. Having this configuration, the deposition with an improved reproducibility in the thickness among the deposited films can be provided by employing the deposition process described in first embodiment. More specifically, in step S102 (FIG. 4), a source material of the TiN film is supplied in deposition reactor 101 through the TiN source material supplying line under the control of the controller 121 to provide pre-coatings with TiN films on the interior wall of the deposition reactor 101, the surface of the boat 105 and the surface of the dummy wafers 109.

The material for the pre-coating film may be of a material that is resistant to being oxidized to form SiO₂. Having such configuration, prevention to the changes in the property of the surface to be deposited of the product wafer 107 and in the film quality of the surface to be deposited of the dummy wafer 109 can be achieved in step S103 of FIG. 4. The supplying line for supplying source gases for the films of such materials may be provided to the deposition apparatus 100, in place of the SiO₂ source material supplying line 115 to achieve the formation of various types of pre-coating films.

In this occasion, a source gas for the base TiN film supplied through the TiN source material supplying line may be, for example, a combination of TiCl₄ and NH₃. Further, tetra dimethyl amino titanium (TDMAT, Ti(NMe₂)₄) may also be employed.

According to the present embodiment, HfO₂ film can be deposited on the TiN film with an improved reproducibility by providing the surface of the TiN film as the surface of the dummy wafer 109, as well as the surface to be deposited of the product wafer 107.

Here, the surface to be deposited of the product wafer 107 may be, in addition to the above described SiO₂ film and TiN film, a metallic film such as Ta film, W film and the like; a metal nitride film such as TaN film, WN film and the like; or a metal oxide film such as TiO₂ film, RuOₓ film (hereinafter, x represents a positive integer number), IrOₓ (hereinafter, x represents a positive integer number) and the like. In these cases, a film of the same type as the film that forms the outermost surface to be deposited of the product wafer 107 as the pre-coating film may be utilized as a pre-coating film to improve the reproducibility in the film thickness among the deposition processes for the high dielectric constant films.

While the preferred embodiments of the present invention have been described above in reference to the annexed figures, it should be understood that the disclosures above are presented for the purpose of illustrating the present invention, and various configurations other than the above described configurations can also be adopted.

For example, the cases of having the pre-coating film composed of the material that is the same as that composing the surface to be deposited of the product wafer 107 before the deposition has been illustrated in the above described embodiment. Alternatively, the pre-coating film may be composed of a material that is different from the material composing the surface to be deposited of the product wafer 107 before the deposition. The condition of depositing a certain film may be closer to the condition for depositing on the surface of the product wafer 107 by providing pre-coating film even in such case. Thus, variation in film thickness of the certain film deposited on the product wafer due to the variation of the number of the product wafer in one batch can be inhibited. For example, the material of the pre-coating film may be a film that provides a deposition rate that is approximately the same level as the deposition rate of, for example, the case for depositing a high dielectric constant film on the surface to be deposited of the product wafer 107.

Further, in the configuration of the above described embodiments, the controller 121 may be configured to provide a sequence, in which information on the material of surface of the dummy wafer and on the material of the surface of the product wafer is referred, and, if these material are different types, then the formation of the pre-coating film is conducted, and if these are similar types, then formation of the pre-coating film is skipped. In this configuration, the deposition apparatus 100 may be configured to comprise a memory section that memorizes information on the material of the surface of the dummy wafer and on the material of the surface of the product wafer.

Further, in the configuration of the above described embodiments, the controller 121 may also be configured to provide a control of an internal temperature of the deposition reactor 101. In such configuration, the deposition apparatus 100 may be additionally configured to comprise a temperature detecting element for detecting a temperature in the deposition reactor 101, to refer the temperature that the controller 121 is detected with the temperature detecting element and to control the operation of heater 111, based on the temperature referred.

Further, in the configuration of the above described embodiments, the deposition apparatus 100 may be additionally configured that the apparatus additionally comprises an accepting section for information on number of product for accepting information on number of the product wafers 107, and that the controller 121 instructs establishing a number of the dummy wafers 109 according to the number of the product wafers 107 accepted by the accepting section for information on number of product, containing an established number of the dummy wafers 109 in the deposition reactor 101, and controlling the quantity of supplied SiO₂ source gas through the SiO₂ source material supplying line 115 depending on the number of the dummy wafers contained therein.

While the above described embodiments have been described in reference to the configuration of conducting the pre-coating of the base SiO₂ film 125 and (S102 of FIG. 4) the deposition of the high-k film (S104 of FIG. 4) by employing one deposition apparatus 100, it may be sufficient that the outermost surface of the dummy wafer 109 is a film that is substantially the same film as the outermost surface of the product wafer 107 when deposition of the high dielectric constant film is conducted. For example, a procedure of preparing a dummy wafer 109 having a base SiO₂ film 125 thereon by using another apparatus, and loading thereof in the deposition reactor 101 of the deposition apparatus 100 upon depositing the high dielectric constant film may also be employed.

When the pre-coating with the base SiO₂ film 125 is conducted using one deposition apparatus 100, then the deposition process of the product wafer 107 can be conducted in the deposition reactor 101 comprising the inside of the reactor wall 103 and the surface of the boat 105 that are surely coated with the base SiO₂ film 125, in addition to the surfaces of the dummy wafers 109. Thus, variation in the film thickness of the thin film deposited on the product wafer 107 can be more surely inhibited, thereby providing an improved reproducibility in the thickness among the deposited films.

Further, the high dielectric constant film deposited on the product wafer 107 in the above described embodiments is preferably used as, for example, a material of a gate insulating film of a field effect transistor, a capacitive film of a capacitor element or the like. Since the high dielectric constant film deposited on the product wafer 107 in the above described embodiment exhibits an improved reproducibility in the thickness among the deposited films, the production yield of the device and the stability in the quality of the product can be improved by employing such materials.

### EXAMPLES

### Example

In the present example, a deposition was carried out in accordance with the deposition sequence (FIG. 2 to FIG. 6) employing the deposition apparatus 100 described in first embodiment (FIG. 1). The deposition procedure will be described as the following (i) to (x):
(i) Ending the deposition of the previous batch (FIG. 2A);
(ii) Unloading the dummy wafers and the product wafers (FIG. 2A);
(iii) Loading the dummy wafers (FIG. 2B);
(iv) Pre-coating the dummy wafers and the interior of the batch type reactor to cover thereof with about 1 to 10 nm thick SiO₂ (FIG. 2B),
(v) Unloading the dummy wafers (FIG. 3A);
(vi) Loading new product wafers (having SiO₂ surface) and the dummy wafers into the batch type reactor (FIG. 3A);
(vii) Depositing HfSiOₓ (1.5 nm) (FIG. 3B);
(viii) Nitriding (FIG. 3B);
(ix) Unloading the dummy wafers and the product wafers (FIG. 2A); and
(x) Measuring the film thickness.

Here, at the time of the step of the above described (i), HfSiOₓ has been deposited on the exposed surface in the interior of the batch type reactor and the surface of the dummy wafers. When the nitriding process has been further conducted in the previous batch, then the deposited film is HfSiON. Further, at the time of the step of the above described (iv), all the exposed surfaces in the interior of the deposition reactor 101, or more specifically, the exposed surfaces of the dummy wafers 109, the product wafers 107, the boat 105, and the inner wall of the reactor wall 103 are of SiO₂ films.

HfSiOₓ and HfSiON were deposited according to the above described procedure, and it is found that the constant film thickness was obtained regardless of the ratio in numbers of the dummy wafers 109 and the product wafers 107, and that higher reproducibility in the thickness among the batches of the HfSiOₓ films and HfSiON films was achieved.

### Comparative Example

A deposition was carried out in accordance with the conventional deposition sequence described above in reference to FIG. 6A and FIG. 6B. The deposition procedure will be described as the following (I) to (VII):
(I) Ending the deposition of the previous batch;
(II) Unloading the dummy wafers 209 and the product wafers 207;
(III) Loading new product wafers 207 (having SiO₂ surface) and the dummy wafers 209 into the deposition reactor 201 (FIG. 6A);
(IV) Depositing HfSiOₓ (1 to 2 nm) (FIG. 6B);
(V) Nitriding (FIG. 6B);
(VI) Unloading the dummy wafers 209 and the product wafers 207; and
(VII) Measuring the film thickness.

Here, at the time of the step of the above described (I), HfSiOₓ has been deposited on the exposed surface in the interior of the batch type reactor and the surface of the dummy wafers. Further, in the step (III), only the surfaces of the product wafers 207 are of SiO₂ surface. In addition, when the nitriding process has been further conducted in the previous batch, then the deposited film is HfSiON.

In this comparative example, it was found that the HfSiOₓ films deposited on the product wafers 207 (SiO₂ film) had fluctuated film thicknesses depending upon the number of dummy wafers 209 in the batch. More specifically, when one piece of product wafer 207 and 24 pieces of dummy wafers 209 were mounted on the boat 205 and loaded in the deposition reactor 101 and the deposition thereon was carried out, the thickness of the HfSiO film on the product wafer 207 was smaller than the thickness of the HfSiO film on the product wafer 207 in the case of similarly conducting the deposition under the condition of mounting 10 pieces of product wafers 207 and 15 pieces of dummy wafers 109 on the boat 205.

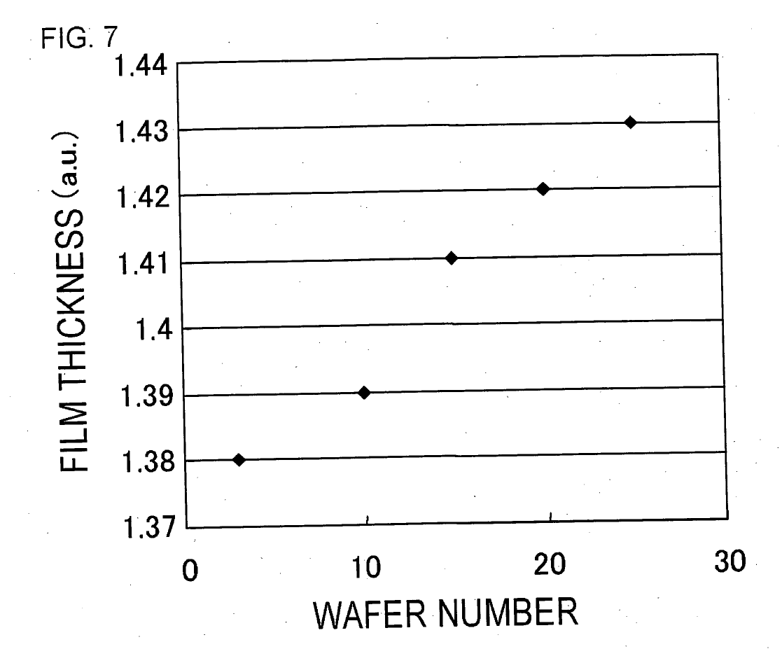

FIG. 7 is a graph, showing a relationship between number of the product wafers 207 and thickness of the HfSiOₓ film. It is found that, in the case of a constant total number of wafers, thickness of the HfSiOₓ film is changed depending on number of the product wafers 207.

It can be seen from the above example and the comparative example that the reproducibility in the thickness among the deposited films can be improved by pre-coating the surfaces of the dummy wafers 109 and the exposed surfaces in the interior of the deposition reactor 101 with the base SiO₂ films 125.

It is apparent that the present invention is not limited to the above embodiment, that may be modified and changed without departing from the scope and spirit of the invention.

What is claimed is:

1. An apparatus for manufacturing a semiconductor device via a batch process, adopted to simultaneously deposit films on a plurality of semiconductor wafers, comprising:
a deposition reactor being capable of containing a product wafer and a dummy wafer in said deposition reactor;
a first gas supplying system that supplies a first gas into said deposition reactor; and
a second gas supplying system that supplies a second gas into said deposition reactor,
wherein said first gas is a source gas for a predetermined film deposited on a surface to be deposited of said product wafer, and
wherein said second gas is a source gas of a pre-coating film, which is to be deposited on said dummy wafer and different in composition from said predetermined film.

2. The apparatus according to claim 1, wherein said predetermined film contains 0 and one or more metal(s) selected from the group consisting of Hf, Al and Zr.

3. The apparatus according to claim 1,
wherein said surface to be deposited of said product wafer is a surface of a film of a metal, a metal oxide or a metal nitride, and
said second gas supplying system is adapted to pre-coating a film in the interior of said deposition reactor, said film being composed of a material that is the same as the material of the film deposited on said surface to be deposited of said product wafer.

4. The apparatus according to claim 3,
wherein said surface to be deposited of said product wafer is a surface of a SiO₂ film, and
said pre-coating film is a SiO₂ film.

5. The apparatus according to claim 3,
wherein said surface to be deposited of said product wafer is a surface of a TiN film, and
said pre-coating film is a TiN film.

6. The apparatus according to claim 1, further comprising a controller that controls said first gas supplying system and said second gas supplying system,
wherein said controller is adapted to supply said second gas to the interior of said deposition reactor from said second gas supplying system while said dummy wafer is contained within said deposition reactor, and to supply said first gas to the interior of said deposition reactor from said first gas supplying system while said dummy wafer having said pre-coating film on a surface of said dummy wafer and said product wafer are contained within said deposition reactor.

7. A method for manufacturing a semiconductor device comprising a deposition process for collectively forming predetermined films on surfaces of a plurality of semiconductor wafers, said deposition process includes:
preparing at least one piece of dummy wafer having a pre-coating film on said dummy wafer, which is different in composition from said predetermined film; and
providing said predetermined films simultaneously on a surface of said dummy wafer prepared in said preparing said dummy wafer and on a surface of a product wafer.

8. The method according to claim 7,
wherein said preparing said dummy wafer includes providing a film on the surface of said dummy wafer, said film being composed of a material that is the same as a material of said surface to be deposited of said product wafer, and
wherein said simultaneously providing said predetermined films includes providing a film of a material that is different from said material of said surface to be deposited of said product wafer.

9. The method according to claim 7,
wherein said preparing the dummy wafer includes containing said dummy wafer within a batch type deposition reactor that is adopted to simultaneously deposit films on a plurality of semiconductor wafers, and providing said pre-coating film on the surface of said dummy wafer and on the wall of said deposition reactor, and
wherein said simultaneously providing said predetermined films is conducted within said deposition reactor having said pre-coating film provided in said deposition reactor.

10. The method according to claim 7, wherein said simultaneously providing said predetermined films includes providing a predetermined film containing 0 and one or more metal(s) selected from the group consisting of Hf, Al and Zr on surfaces of said dummy wafer and said product wafer.

11. The method according to claim 10, wherein said predetermined film is a film further containing elemental Si and/or elemental N.

12. The method according to claim 7, wherein a surface to be deposited of said product wafer is a surface of a film composed of any of a metal, a metal oxide and a metal nitride.

13. The method according to claim 7,
wherein a surface to be deposited of said product wafer is a surface of a SiO₂ film, and
wherein said preparing the dummy wafer includes pre-coating a SiO₂ film on a surface of said dummy wafer.

14. The method according to claim 7, wherein a surface to be deposited of said product wafer is a surface of a TiN film, and
wherein said preparing the dummy wafer includes pre-coating a TiN film on a surface of said dummy wafer.
